(19) United States
(12) Patent Application Publication
(10) Pub. No.: US 2026/0182318 A1
(43) Pub. Date: Jun. 25, 2026

(54) TRENCH DEVICE AND MANUFACTURING METHOD THEREOF

(71) Applicant: HANGZHOU FULLSEMI SEMICONDUCTOR CO., LTD., Hangzhou (CN)

(72) Inventors: Shimin WANG, Hangzhou (CN); Wei ZHOU, Hangzhou (CN); Yangming GUO, Hangzhou (CN); Chaocheng LI, Hangzhou (CN)

(73) Assignee: HANGZHOU FULLSEMI SEMICONDUCTOR CO., LTD., Hangzhou (CN)

(21) Appl. No.: 19/314,027

(22) Filed: Aug. 29, 2025

(30) Foreign Application Priority Data
Dec. 25, 2024 (CN) 2024119433395

(51) Int. Cl. H01L 21/762; H01L 21/02

(52) U.S. Cl. CPC H10W 10/014; H10P 70/20; H10W 10/17

(57) ABSTRACT

The manufacturing method in the present disclosure include: providing a semiconductor structure including a substrate, a first oxide layer, a hard mask layer, and a dielectric layer, which are sequentially stacked; forming a first photoresist layer on the dielectric layer; performing patterning etching on a critical device region of the semiconductor structure from the first photoresist layer, to form at least one first window that through the hard mask layer and the dielectric layer to the first oxide layer; removing the first photoresist layer, and cleaning residues from the first window; and forming a second photoresist layer on the dielectric layer. The present disclosure eliminates impurities and initial defects in the critical device region, so that the formation of conical defects in a trench isolation structure in the critical device region is avoided, thus having broad applicability and a low cost.

### FIELD OF THE INVENTION

The present disclosure relates to the technical field of semiconductor technology, in particular to a trench device and a manufacturing method thereof.

### BACKGROUND OF THE INVENTION

Conical defects are common in trench isolation structures, and they arise when impurities on a material surface locally inhibit the etching process. Initially, dot-like or relatively small conical defects are formed in an impurity region, and as subsequent layers are further etched, materials accumulate and deposit around the defects, causing the dot-like or small conical defects to grow into relatively large defect structures. The above-described conical defects can only be detected after etching, and current processes are unable to remove the conical defects, leading to chip short-circuit failures or a series of reliability issues. Especially when the defects are located in a high-voltage device region, the yield of the chip can be substantially reduced.

### SUMMARY OF THE INVENTION

In a first aspect, the present disclosure provides a method for manufacturing a trench device, including:
providing a semiconductor structure, wherein the semiconductor structure includes a substrate, a first oxide layer, a hard mask layer, and a dielectric layer, which are sequentially stacked;
forming a first photoresist layer on a side of the dielectric layer away from the hard mask layer;
performing patterning etching on a critical device region of the semiconductor structure from the first photoresist layer, to form in the critical device region at least one first window that through the hard mask layer and the dielectric layer to the first oxide layer;
removing the first photoresist layer, and cleaning residues from the first window; and
forming a second photoresist layer stacked on the dielectric layer, wherein the second photoresist layer fills the first window.

In an embodiment, after forming the second photoresist layer stacked on the dielectric layer, the manufacturing method further includes:
performing patterning etching on a non-critical device region of the semiconductor structure from the second photoresist layer, to form at least one second window that through the hard mask layer and the dielectric layer to the first oxide layer;
removing the second photoresist layer; and
etching the substrate based on the first window and the second window, to form a first trench corresponding to the first window and a second trench corresponding to the second window.

In an embodiment, before etching the substrate based on the first window and the second window, to form the first trench corresponding to the first window and the second trench corresponding to the second window, the manufacturing method further includes:
cleaning residues from the second window.

In an embodiment, providing the semiconductor structure includes:
providing the substrate;
forming the first oxide layer on the substrate;
depositing the hard mask layer on a side of the first oxide layer away from the substrate; and
depositing the dielectric layer on a side of the hard mask layer away from the first oxide layer.

In an embodiment, the dielectric layer includes an anti-reflection layer and a second oxide layer, which are sequentially stacked on the hard mask layer.

In an embodiment, the anti-reflection layer is made of an inorganic material.

In an embodiment, the anti-reflection layer is made of one or more of silicon oxynitride, magnesium fluoride, aluminum oxide, titanium dioxide, zirconium dioxide, silicon nitride, and zinc oxide.

In an embodiment, an acid etching solution is used in the process of cleaning the residues, and the first oxide layer is chemically inert to the acid etching solution.

In an embodiment, the acid etching solution includes phosphoric acid.

In a second aspect, the present disclosure further discloses a trench device, which is manufactured based on the above-described manufacturing method.

In an embodiment, the trench device includes a substrate, a first oxide layer, a hard mask layer, and a dielectric layer, which are sequentially stacked, as well as a first window, a second window, a first trench, and a second trench;
the first window is located in a critical device region of the substrate and through the first oxide layer, the hard mask layer, and the dielectric layer, and the second window is located in a non-critical device region of the substrate and through the first oxide layer, the hard mask layer, and the dielectric layer; and
the first trench is located in a region corresponding to the first window and formed in the substrate, and the second trench is located in a region corresponding to the second window and formed in the substrate.

In a third aspect, the present disclosure further provides an integrated circuit including the above-described trench device.

In a fourth aspect, the present disclosure further provides an electronic apparatus including the above-described trench device.

Based on the above technical solution, the present disclosure has the following beneficial effects:

In the technical solution of the present disclosure, a first photoresist layer is formed on a side of the dielectric layer away from the hard mask layer, and patterning etching is performed on a critical device region of the semiconductor structure from the first photoresist layer, to form in the critical device region at least one first window that through the hard mask layer and the dielectric layer to the first oxide layer, thereby achieving mask patterning of the critical device region. Later, the first photoresist layer is removed and residues are cleaned from the first window, and then a second photoresist layer is formed, wherein the second photoresist layer fills the first window, thereby eliminating impurities and initial defects in the critical device region to some extent and achieving protection of a corresponding region in a subsequent process. This allows the formation of conical defects in a trench isolation structure in the critical device region to be avoided, and the device performance and product yield to be ensured. Moreover, in this approach, only the first photoresist layer needs to be added as a photomask, making it adaptable to various device processes with broad applicability and a low cost.

### BRIEF DESCRIPTION OF DRAWINGS

To describe the technical solution in embodiments of the present disclosure more clearly, drawings in the description of the embodiments will be introduced briefly below. Obviously, the drawings described below merely represent some embodiments of the present disclosure, and those of ordinary skill in the art can obtain other drawings according to these drawings without creative efforts.

FIG. 1 is a schematic flow diagram of an exemplary method for manufacturing a trench device in the present disclosure.

FIGS. 2 to 9 are schematic cross-sectional diagrams showing a manufacturing process of a trench device according to an embodiment of the present disclosure.

FIG. 10 is a schematic cross-sectional diagram showing a manufacturing process of a trench device in a comparative example of the present disclosure.

Reference Numerals

| | | | |
|---|---|---|---|
| 10 | impurity particle | 20 | initial defect |
| 30 | conical defect | 40 | anti-reflection coating |
| 50 | photoresist layer | 100 | substrate |
| 101 | critical device region | 210 | first oxide layer |
| 220 | hard mask layer | 230 | dielectric layer |
| 231 | anti-reflection layer | 232 | second oxide layer |
| 310 | first photoresist layer | 320 | second photoresist layer |
| 410 | first window | 420 | second window |
| 430 | first trench | 440 | second trench |

### DETAILED DESCRIPTION OF THE INVENTION

The technical solution in the embodiments of the present disclosure will be described below clearly and completely in conjunction with the accompanying drawings in the embodiments of the present disclosure. Apparently, the embodiments described are merely part rather than all of the embodiments of the present disclosure. All other embodiments obtained by those of ordinary skill in the art based on the embodiments of the present disclosure without creative efforts fall within the scope of protection of the present disclosure.

The term “one embodiment” or “an embodiment” as used herein refers to a specific feature, structure, or characteristic that may be included in at least one implementation of the present disclosure. In the description of the present disclosure, it is to be understood that orientation or positional relationships indicated by the terms such as “upper”, “lower”, “top”, “bottom”, and the like are based on orientations or positional relationships shown in the drawings, and are merely for the convenience of describing the present disclosure and simplifying the description, rather than indicating or implying that the denoted apparatuses or components necessarily have specific orientations or are constructed and operated in specific orientations. Therefore, such terms should not be construed as limiting the present disclosure. In addition, the terms “first” and “second” are used only for descriptive purposes and should not be construed as indicating or implying relative importance or implicitly specifying the number of indicated technical features. Thus, a feature described by the term “first” or “second” may explicitly or implicitly include one or more such features. Moreover, the terms “first”, “second”, and the like are used for distinguishing similar objects and do not describe a specific order or sequence. It should be understood that the order or sequence used is interchangeable under appropriate circumstances, so that the embodiments of the present disclosure described herein can be implemented in an order other than those illustrated or described herein.

When a range of values is disclosed herein, this range is considered to be continuous and includes a minimum and a maximum value of the range, as well as every value between such minimum and maximum values. Further, when the range refers to integers, it includes every integer between the minimum and maximum values of the range. In addition, when a plurality of ranges are provided to describe features or characteristics, the ranges may be combined. In other words, unless otherwise specified, all ranges disclosed herein should be understood as including any and all sub-ranges thereof. For example, a specified range from “1 to 10” should be considered to include any and all sub-ranges between a minimum value of 1 and a maximum value of 10. Exemplary sub-ranges of the range from 1 to 10 include, but are not limited to, 1 to 6.1, 3.5 to 7.8, 5.5 to 10, etc.

The term “layer” as used in the present disclosure refers to a material that includes a region having a certain thickness. The layer may extend over an entire underlying or overlying structure, or may extend over only a partial region of the underlying or overlying structure. In addition, the layer may be a region of a homogeneous or inhomogeneous continuous structure, and its thickness may be less than that of the continuous structure. For example, the layer may be located between a top surface and a bottom surface of the continuous structure or between any pair of horizontal planes therebetween. The layer may extend horizontally, vertically, and/or along a profiled surface. A layer may include a plurality of sub-layers. For example, a dielectric layer 230 may include a plurality of sub-layers, etc., and the sub-layers may have the same or different materials.

It should be understood that the limitations such as “consistent” and “perpendicular” mean substantially consistent or substantially perpendicular within process tolerances, and do not refer to absolute consistency or absolute perpendicularity in a physical sense.

It should be understood that the term “plane”, such as “first plane”, “second plane”, etc., as used in the present disclosure, refers to an XY plane of a substrate 100 or a substrate structure, etc., corresponding to an XY plane of a trench device; an “in-plane direction” refers to a direction parallel to the XY plane; and a “thickness direction”, a “trench depth direction”, or a “longitudinal direction” refers to a z-direction with respect to the XY plane.

In current processes, the formation of conical defects is mainly attributed to the presence of metal ions in a developer used for photoresist coating, or the presence of impurities in an anti-reflection coating formed by organic solution coating. In the prior art, the conical defects are reduced by decreasing the metal ion content in the developer, or using filters with different pore sizes and materials to filter out impurities from an organic solution in order to reduce the impurities in the coating. However, the former approach is costly and cannot be universally applied to different chip manufacturing processes and production lines, and in the latter solution, even an optimal filter cannot completely filter out the impurities, meaning that the conical defects cannot be completely avoided.

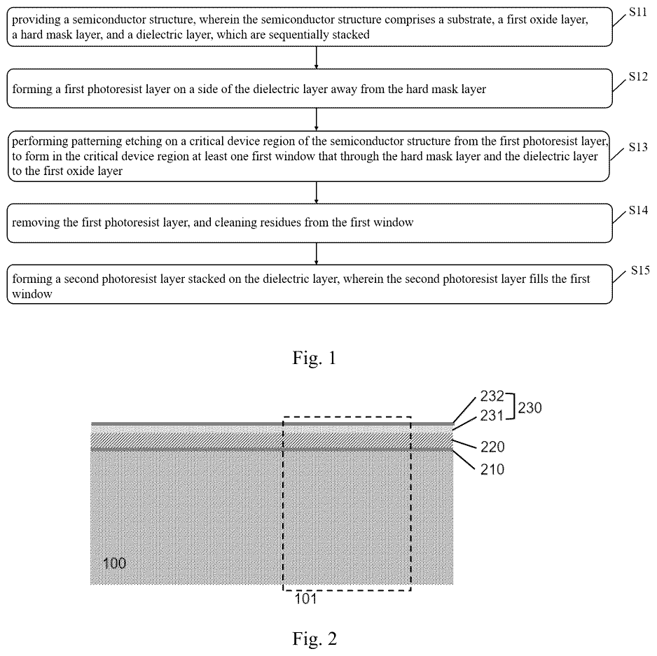

A method for manufacturing a trench device according to embodiments of the present disclosure is described below in conjunction with FIGS. 1 to 9. FIG. 1 is a schematic flow diagram of the method for manufacturing a trench device. The present specification provides operation steps of the method in the embodiments or flow diagrams, however, it should be noted that more or fewer steps may be included based on conventional or non-inventive efforts. The order of the steps listed in the embodiments is merely one of numerous step execution orders, and does not represent the only execution order. When the manufacturing method is executed in practice, the method may be executed in the order illustrated in the embodiments or drawings, or executed in parallel. Referring to FIG. 1, the manufacturing method may include S11 to S15:

S11: providing a semiconductor structure.

Specifically, referring to FIG. 2, the semiconductor structure includes a substrate 100, a first oxide layer 210, a hard mask layer 220, and a dielectric layer 230, which are sequentially stacked.

Specifically, the substrate 100 is a semiconductor substrate body suitable for semiconductor device processing. Exemplarily, the substrate 100 may be made of at least one of silicon, silicon-containing materials (III-V compound semiconductor materials such as gallium arsenide (GaAs)), and silicon on insulator (SOI), or other types of semiconductor materials capable of forming the substrate 100.

In some embodiments, the substrate 100 may include a substrate layer and an epitaxial layer, with the first oxide layer 210 being stacked on the epitaxial layer. The substrate layer may be made of at least one of silicon, silicon-containing materials (III-V compound semiconductor materials such as gallium arsenide (GaAs)), and silicon on insulator (SOI), or other types of semiconductor materials capable of forming the substrate 100. Optionally, the epitaxial layer may be specifically formed by an epitaxial growth process. The epitaxial layer may be a homoepitaxial layer, which grows continuously along a lattice direction of the substrate layer to form the epitaxial layer, or may be a heteroepitaxial layer. Process conditions such as specific growth temperature may be the same as those in an existing process, or may be adaptively adjusted. Optionally, the epitaxial layer may be formed by chemical vapor deposition (CVD), physical vapor deposition (PVD), atomic layer deposition (ALD), or other methods. Exemplarily, the epitaxial layer may be made of silicon, germanium, gallium arsenide, gallium phosphide (GaP), gallium nitride (GaN), etc., or may be other materials capable of epitaxial growth or suitable for device region processing after being deposited on the substrate layer.

In some embodiments, the providing of the semiconductor structure in S11 may further include S111 to S114:
S111: providing the substrate 100;
S112: forming the first oxide layer 210 on the substrate 100;
S113: depositing the hard mask layer 220 on a side of the first oxide layer 210 away from the substrate 100; and
S114: depositing the dielectric layer 230 on a side of the hard mask layer 220 away from the first oxide layer 210.

Specifically, the first oxide layer 210 covers at least a portion of a surface of the substrate 100, and it can protect the material of the substrate 100 during the device preparation process and can serve as an insulating layer. Optionally, the first oxide layer 210 may be formed at least based on a deposition process. The deposition process includes, but is not limited to, low pressure chemical vapor deposition, plasma-enhanced chemical vapor deposition, sub-atmospheric chemical vapor deposition, high-density plasma chemical vapor deposition, atomic layer deposition, plasma-enhanced atomic layer deposition, and the like. Exemplarily, HDPCVD may be used to form the first oxide layer 210, and the first oxide layer 210 may be made of, but is not limited to, silicon oxide. In some embodiments, a process of forming the first oxide layer 210 may include: forming a first initial oxide layer on a side of the substrate 100 based on a deposition process; and performing chemical mechanical planarization on the first initial oxide layer until a desired thickness is reached to form the first oxide layer 210. It is to be noted that the first oxide layer 210 may also be formed by a thermal oxidation process or other processes, without being limited by the above example.

Specifically, the hard mask layer 220 covers at least a critical device region 101 of the substrate 100 and a non-critical device region where trench etching is to be performed, and the hard mask layer is used to form a patterned window for trench etching. Optionally, the hard mask layer may specifically be made of at least one of silicon nitride, titanium nitride, silicon dioxide, etc., and the hard mask may be formed by chemical vapor deposition or other processes, wherein the chemical vapor deposition includes plasma-enhanced chemical vapor deposition, high-density plasma chemical vapor deposition, sub-atmospheric chemical vapor deposition, low pressure chemical vapor deposition, atomic layer deposition, plasma-enhanced atomic layer deposition, or other types of chemical vapor deposition processes. Exemplarily, the hard mask layer is a SIN layer made of silicon nitride.

Specifically, the dielectric layer 230 is stacked on the hard mask layer 220, and has an anti-reflection effect during etching to reduce reflection of light during lithography, thereby improving the resolution and accuracy of lithography. Moreover, the dielectric layer 230 can also achieve an isolating and protective effect, further ensuring that underlying materials are protected from an etching agent.

Specifically, the dielectric layer 230 is formed at least by a deposition process, such as the various vapor deposition methods in the above-described examples. In some embodiments, the dielectric layer 230 includes an anti-reflection layer 231 and a second oxide layer 232, which are sequentially stacked on the hard mask layer 220. The second oxide layer 232 is similar to the above-described first oxide layer 210 in terms of manufacturing method, material, etc., which will not be described here. The anti-reflection layer 231 is formed on the hard mask layer 220 by a deposition process, and cooperates with the second oxide layer 232 to achieve an anti-reflection effect.

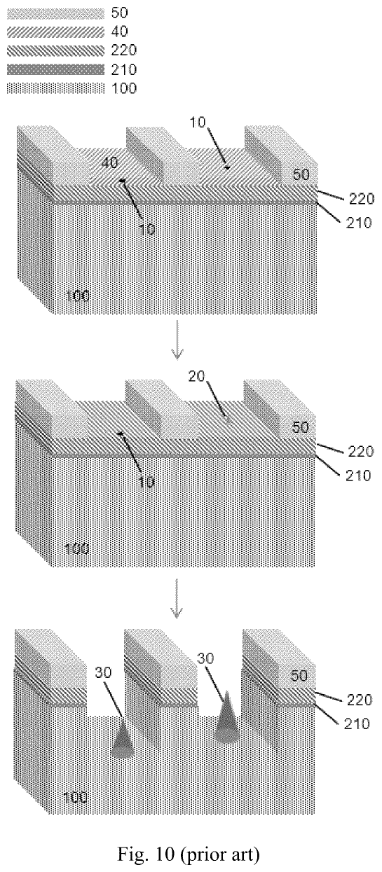

In an existing process, referring to FIG. 10, typically, only one layer of anti-reflection coating 40 is formed on the hard mask layer 220 to achieve an anti-reflection effect during lithography, and the anti-reflection coating 40 is usually formed by a coating process, such as a bottom anti-reflection coating (BARC). Materials used to form the anti-reflection coating typically include crosslinkable resins, thermal acid generators, surfactants, solvents, etc. Impurities are inevitably present in the above-mentioned coating materials, therefore, filters of different pore sizes and materials are used to filter out the impurities from the BARC. However, even if an optimal filter is adopted, the impurities cannot be completely filtered out, which means that conical defects 30 are inevitably formed, moreover, the filtration cost is high. The technical solution of this embodiment adopts a precipitation method to form the anti-reflection layer 231 and the second oxide layer 232, which cooperatively achieve an anti-reflection function, a protecting and isolating effect, and eliminate the need to apply a coating solution to form the anti-reflection coating 40, thus avoiding the introduction of impurities into the overall device due to the formation of the coating and the formation of the conical defects 30 caused by such impurities.

In some embodiments, the anti-reflection layer is made of an inorganic material, which facilitates material deposition and ensures the reflection protection performance of the dielectric layer 230.

In some embodiments, the anti-reflection layer 231 may be made of one or more of silicon oxynitride, magnesium fluoride, aluminum oxide, titanium dioxide, zirconium dioxide, silicon nitride, and zinc oxide, or other inorganic material capable of forming the anti-reflection layer 231. Exemplarily, the anti-reflection layer 231 is made of silicon oxynitride (SION), and the hard mask layer 220 is made of silicon nitride (SIN). Accordingly, the SION layer not only can serve as the anti-reflection layer 231, but also cooperates with the SIN to enhance the performance of the mask layer and ensure the patterning quality of trench etching.

S12: forming a first photoresist layer 310 on a side of the dielectric layer 230 away from the hard mask layer 220.

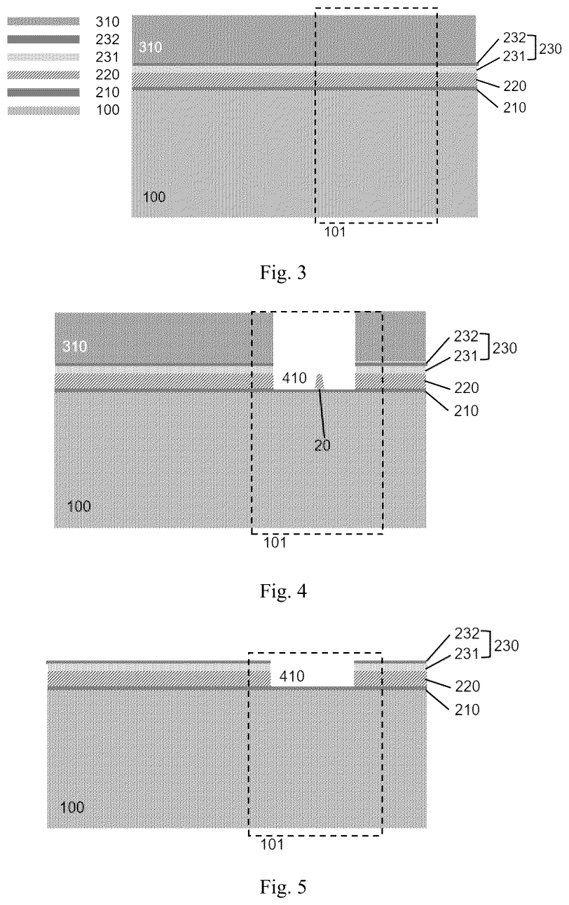

Specifically, referring to FIGS. 3 and 4, the first photoresist layer 310 is used to form a photomask (Mask) for patterning the mask layer in the critical device region 101, and is capable of undergoing a chemical reaction during exposure process so that exposed and unexposed regions exhibit different solubilities towards a developer, thereby forming a desired pattern and transferring a pre-designed pattern to the mask layer. Optionally, the first photoresist layer 310 may be formed on the dielectric layer 230 by a coating process, specifically, pre-baking is performed to remove solvents from a photoresist solution of the coating process, and solidifying is then performed to obtain the first photoresist layer 310. The first photoresist layer 310 is subjected to an exposure process to expose a to-be-etched region of the critical device region 101, and the exposed or unexposed region is then dissolved by using the developer to form the pattern, thereby achieving the pattern transfer in the critical device region 101. In some cases, a post-baking process may also be used to further solidify the photoresist layer to improve its stability and corrosion resistance. Optionally, the first photoresist layer 310 may be made of one or more of polyimide (PI), phenolic resin (Novolac), acrylic resin, epoxy resin, and silicon-based photoresist materials, or other materials that can be used for lithographic exposure and development.

S13: performing patterning etching on the critical device region 101 of the semiconductor structure from the first photoresist layer 310, to form in the critical device region 101 at least one first window 410 that through the hard mask layer 220 and the dielectric layer 230 to the first oxide layer 210.

Specifically, the first window 410 is used to form a first trench 430 of the critical device region 101. After exposure and development are performed on the first photoresist layer 310, the first photoresist layer 310 exposes a region corresponding to the first window 410, and then etching of the dielectric layer 230 and the hard mask layer 220 is carried out to expose the first oxide layer 210, so as to form the first window 410.

Understandably, due to the presence of metal ions or other impurities in the developer, which affects the etching of the dielectric layer 230 and the hard mask layer 220, an initial defect 20 formed by residues of the dielectric layer 230 or the hard mask layer 220 may be present in a region exposing the first oxide layer 210 after the formation of the first window 410, as shown in FIG. 4. The initial defect 20 may affect subsequent etching of the first oxide layer 210 and the substrate. The first window 410 may be formed by using a dry etching or wet etching process, preferably a dry etching process.

S14: removing the first photoresist layer 310, and cleaning residues from the first window 410.

Specifically, residue cleaning may be performed before the removal of the first photoresist layer 310 or after the removal of the first photoresist layer 310, to remove the impurities or initial defect 20 as described above, so that the initial defect 20 is prevented from forming a conical defect 30 during a subsequent trench etching process. The conical defect 30, also known as a cone defect, is very common in shallow trench isolation (STI). Referring to FIG. 5, after residue cleaning, the initial defect 20 formed within the first window 410 is removed. In this way, the first photoresist layer 310 serves as a conical defect reduction mask (CDR mask) for the critical device region 101, which facilitates the removal of the impurities and defects generated during patterning of the critical device region 101.

In some embodiments, an acid etching solution is used in the process of residue cleaning. The first oxide layer 210 is chemically inert to the acid etching solution, so that the initial defect 20 formed by the residues is selectively removed while retaining the first oxide layer 210 for subsequent trench etching. It may be understood that a main component of the initial defect 20 is the material of the hard mask layer 220. The initial defect 20 is chemically active to the acid etching solution and can be etched away.

In some embodiments, the acid etching solution includes phosphoric acid. The acid etching solution is able to remove the initial defect 20 made of materials including silicon nitride or the like, thereby preventing the formation of a conical defect 30 in the critical device region 101 and significantly reducing a yield loss due to the defect.

S15: forming a second photoresist layer 320 stacked on the dielectric layer 230.

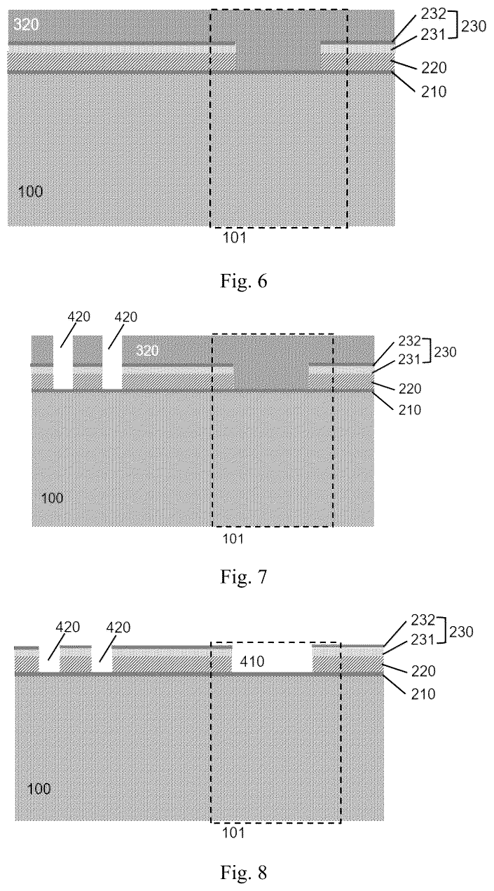

Specifically, referring to FIG. 6, the second photoresist layer 320 fills the first window 410 to avoid the introduction of impurities and structural damage from a subsequent etching process, protecting the cleanliness and structural integrity of the first window 410. More specifically, the second photoresist layer 320 further covers the critical device region 101 and at least a portion of the non-critical device region, for subsequent pattern transfer in the non-critical device region 101. The second photoresist layer 320 is similar to the above-described first photoresist layer 310 in terms of manufacturing method and material, which will not be described here. The first photoresist layer 310 and the second photoresist layer 320 may or may not be made of the same materials, and selection may be specifically determined based on actual needs. Preferably, the second photoresist layer 320 may cover an active area (AA) of the substrate 100.

Specifically, the critical device region 101 is a region where the device performance of the trench device is affected or greatly affected by conical defects 30, such as a high-voltage device region or a high-resistance polycrystalline silicon (HR Poly) resistor region, etc. The conical defect 30 in the critical device region 101 has a crucial impact on a product yield, and can lead to problems such as leakage current and reduced breakdown voltage, resulting in a yield loss.

In the technical solution of the present disclosure, the first photoresist layer 310 is formed on a side of the dielectric layer 230 away from the hard mask layer 220. Then patterning etching is performed on the critical device region 101 of the semiconductor structure from the first photoresist layer 310, to form in the critical device region 101 at least one first window 410 that through the hard mask layer 220 and the dielectric layer 230 to the first oxide layer 210. Thus, mask patterning of the critical device region 101 is achieved. Subsequently, the first photoresist layer 310 is removed, and residues are cleaned from the first window 410. Afterwards, the second photoresist layer 320 is formed, wherein the second photoresist layer 320 fills the first window 410, thereby preventing impurities and initial defects 20 in the critical device region 101 to some extent and achieving protection of a corresponding region in a subsequent process. As a result, the formation of conical defects 30 in a trench isolation structure in the critical device region 101 can be avoided, and device performance and product yield are ensured. Moreover, in the method of the present disclosure, only the first photoresist layer 310 needs to be added as a photomask, making it adaptable to various device processes with broad applicability and a low cost.

Based on some or all of the above embodiments, in some embodiments, after S15, referring to FIGS. 7 to 9, the manufacturing method further includes S21 to S23:
S21: performing patterning etching on a non-critical device region of the semiconductor structure from the second photoresist layer 320, to form at least one second window 420 that through the hard mask layer 220 and the dielectric layer 230 to the first oxide layer 210;
S22: removing the second photoresist layer 320; and
S23: etching the substrate based on the first window 410 and the second window 420, to form a first trench 430 corresponding to the first window 410 and a second trench 440 corresponding to the second window 420.

Specifically, the non-critical device region is a region where device performance is not affected or barely affected by conical defects 30, such as a region serves only as an isolation without other functions in the trench isolation structure, therefore, the presence of a certain amount of conical defects 30 does not excessively affect the performance and yield. The second photoresist layer 320 is used as an etching photomask for the non-critical device region. After the second photoresist layer 320 undergoes exposure and development, a region corresponding to the second window 420 in the non-critical device region is exposed, and then, the dielectric layer 230 and the hard mask layer 220 are etched to expose the first oxide layer 210, thus forming the second window 420. Pattern transfer in the non-critical device region is achieved, which facilitates the etching of the second trench 440. Specifically, the etching of the second window 420 may be performed by a dry etching process or a wet etching process, preferably by a dry etching process. By using the first photoresist layer 310 and the second photoresist layer 320, respectively, as the photomasks for the critical device region 101 and the non-critical device region, the pattern transfer in these two regions is decoupled. This allows removal of the conical defect 30 in the critical device region 101, while reducing the scope of residue cleaning, decreasing the complexity of an impurity removal process, and reducing film damage.

As previously described, the dielectric layer 230 can achieve anti-reflection performance, and includes the anti-reflection layer 231 and the second oxide layer 232. This structure avoids the use of the anti-reflection coating 40 that needs to perform coating. Defects caused by the introduction of impurities from a coating solution into the critical device region 101 and the non-critical device region no longer exist, so that the number of conical defects 30 in the non-critical device region is also substantially reduced, thereby further optimizing the device performance.

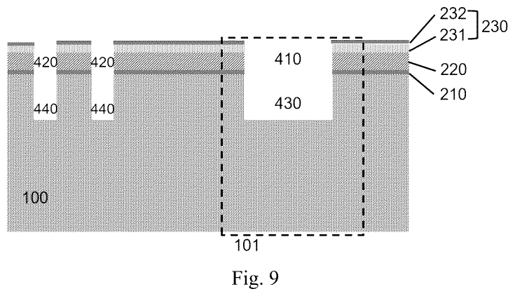

Further, referring to FIGS. 8 and 9, in this embodiment, after the formation of the first window 410 and the second window 420, the second photoresist layer 320 is removed and the trench etching based on the first window 410 and the second window 420 can be carried out at the same time without altering the trench etching step in conventional process, which reduce the cost of process modification. The first trench 430 and the second trench 440 are trench structures respectively formed in the critical device region 101 and the non-critical device region, and are subsequently filled to form corresponding functional structures. In some embodiments, the first trench 430 and the second trench 440 are shallow trenches, and are used to form shallow trench isolation (STI).

In some embodiments, before S23, the manufacturing method further includes S31: cleaning residues from the second window 420. The residue cleaning here is similar to the cleaning process in the above-described S14, which will not be described here. By performing cleaning after the formation of the second window 420, the initial defect 20 in the non-critical device region caused by the developer can be removed, thereby improving the homogeneity of the overall trench isolation structure of the device.

In order to better illustrate the technical effects of the technical solution of the present disclosure, a conventional manufacture process in a comparative example is introduced below in conjunction with FIG. 10. Specifically, a method for manufacturing a trench device according to the comparative example specifically includes the following steps: providing a semiconductor structure in which a substrate 100, a first oxide layer 210, a hard mask layer, and an anti-reflection coating 40 sequentially stacked; forming a photoresist layer 50 on a side of the anti-reflection coating 40 away from the hard mask layer 220; forming a to-be-etched window region of the device after exposure and development, performing cleaning to remove the anti-reflection coating 40 and etching the hard mask layer 220, and then performing trench etching to form a trench structure in the substrate 100. As shown in FIG. 10, impurity particles 10 are present in the anti-reflection coating 40, and impurity particles 10 are also present after development of the photoresist layer 50. After removal of the anti-reflection coating 40, an initial defect 20 is formed at a position of impurity particles generated by the development of the photoresist layer. As the subsequent etching process proceeds, the defect becomes larger and larger due to material accumulation, and a large conical defect 30 is finally formed. Main body components of the defect are the material of the hard mask and the material of the substrate 100. A trench isolation structure subsequently prepared in this comparative example carrying the conical defect 30 inevitably has a degraded performance of the critical device region 101, resulting in a yield loss.

In the technical solution of the present disclosure, the first photoresist layer 310 is formed on a side of the dielectric layer 230 away from the hard mask layer 220, and patterning etching is performed on the critical device region 101 of the semiconductor structure from the first photoresist layer 310, to form in the critical device region 101 at least one first window 410 that through the hard mask layer 220 and the dielectric layer 230 to the first oxide layer 210, thereby achieving mask patterning of the critical device region 101. Later, the first photoresist layer 310 is removed and residues are cleaned from the first window 410, and then the second photoresist layer 320 is formed, wherein the second photoresist layer 320 fills the first window 410, thereby avoiding impurities and initial defects 20 in the critical device region 101 to some extent and achieving protection of a corresponding region in a subsequent process. This prevents the formation of conical defects 30 in a trench isolation structure in the critical device region 101 and ensures device performance and product yield. Moreover, in this approach, only the first photoresist layer 310 needs to be added as a photomask, making it adaptable to various device processes with broad applicability and a low cost. Further, by using the anti-reflection layer 231 and the second oxide layer 232, impurity-induced defects introduced by the anti-reflection coating 40 can be avoided, thereby substantially reducing conical defects 30 in the overall region of the device, and improving the performance and yield of the device.

Embodiments of the present disclosure further provide a trench device, which is manufactured based on the above-described manufacturing method.

In some embodiments, the trench device specifically includes a substrate 100, a first oxide layer 210, a hard mask layer 220, and a dielectric layer 230, which are sequentially stacked, as well as a first window 410, a second window 420, a first trench 430, and a second trench 440.

The first window 410 is located in a critical device region 101 of the substrate 100 and through the first oxide layer 210, the hard mask layer 220, and the dielectric layer 230, and the second window 420 is located in a non-critical device region of the substrate 100 and through the first oxide layer 210, the hard mask layer 220, and the dielectric layer 230.

The first trench 430 is located in a region corresponding to the first window 410 and formed in the substrate 100, and the second trench 440 is located in a region corresponding to the second window 420 and formed in the substrate 100.

Embodiments of the present disclosure further provide an electronic apparatus including the above-described trench device. Specifically, the electronic apparatus includes the trench device and an electronic component connected to the trench device.

The electronic apparatus in the embodiments of the present disclosure may be selected from any electronic product or apparatus such as a cell phone, a handheld computer (personal digital assistant, PDA), a tablet computer (pad), a notebook computer, a game console, a television, a video compact disc (VCD), a digital video disc (DVD), a navigator, a camera, a camcorder, a voice recording pen, an MP3 player, an MP4 player, and a handheld game console (Play Station Portable, PSP), or may be any intermediate product that includes an electronic device manufactured based on the above-described trench device.

It is to be noted that the order of the above embodiments of the present disclosure is for descriptive purposes only, and does not indicate the relative merits of the embodiments. Particular embodiments in this specification are described above. Other embodiments are still within the scope of the appended claims. In some cases, actions or steps recited in the claims may be performed in an order different from that in the embodiments, and can still achieve an expected result. In addition, the processes depicted in the accompanying drawings do not necessarily require the illustrated particular order or consecutive order to achieve an expected result. In some implementations, multitasking and parallel processing are also possible or may be advantageous.

The embodiments in the specification are all described in a progressive manner. For parts that are the same or similar among the embodiments, reference may be made to each other. Description of each embodiment focuses on differences from other embodiments. In particular, since an apparatus embodiment is substantially similar to a method embodiment, the apparatus embodiment is described in a relatively simple manner, and for relevant parts, reference may be made to the description of corresponding parts in the method embodiment.

Those of ordinary skill in the art can understand that all or part of the steps in the above embodiments may be implemented by hardware, or by relevant hardware instructed by a program. The program may be stored in a computer readable storage medium. The above-mentioned storage medium may be a read only memory, a magnetic disk, an optical disc, or the like.

Described above are merely preferred embodiments of the present disclosure, which are not intended to limit the present disclosure, and all modifications, equivalent substitutions, and improvements made within the spirit and principle of the present disclosure should be within the protection scope of the present disclosure.

1. A method for manufacturing a trench device, comprising:
providing a semiconductor structure, wherein the semiconductor structure comprises a substrate, a first oxide layer, a hard mask layer, and a dielectric layer, which are sequentially stacked;
forming a first photoresist layer on a side of the dielectric layer away from the hard mask layer;
performing patterning etching on a critical device region of the semiconductor structure from the first photoresist layer, to form in the critical device region at least one first window that through the hard mask layer and the dielectric layer to the first oxide layer;
removing the first photoresist layer, and cleaning residues from the first window; and
forming a second photoresist layer stacked on the dielectric layer, wherein the second photoresist layer fills the first window.

2. The manufacturing method according to claim 1, wherein after forming the second photoresist layer stacked on the dielectric layer, the manufacturing method further comprises:
performing patterning etching on a non-critical device region of the semiconductor structure from the second photoresist layer, to form at least one second window that through the hard mask layer and the dielectric layer to the first oxide layer;
removing the second photoresist layer; and
etching the substrate based on the first window and the second window, to form a first trench corresponding to the first window and a second trench corresponding to the second window.

3. The manufacturing method according to claim 2, wherein before etching the substrate based on the first window and the second window, to form the first trench corresponding to the first window and the second trench corresponding to the second window, the manufacturing method further comprises:
cleaning residues from the second window.

4. The manufacturing method according to claim 1, wherein providing the semiconductor structure comprises:
providing the substrate;
forming the first oxide layer on the substrate;
depositing the hard mask layer on a side of the first oxide layer away from the substrate; and
depositing the dielectric layer on a side of the hard mask layer away from the first oxide layer.

5. The manufacturing method according to claim 1, wherein the dielectric layer comprises an anti-reflection layer and a second oxide layer, which are sequentially stacked on the hard mask layer.

6. The manufacturing method according to claim 5, wherein the anti-reflection layer is made of an inorganic material.

7. The manufacturing method according to claim 5, wherein the anti-reflection layer is made of one or more of silicon oxynitride, magnesium fluoride, aluminum oxide, titanium dioxide, zirconium dioxide, silicon nitride, and zinc oxide.

8. The manufacturing method according to claim 1, wherein an acid etching solution is used in the process of cleaning the residues, and the first oxide layer is chemically inert to the acid etching solution.

9. The manufacturing method according to claim 8, wherein the acid etching solution comprises phosphoric acid.

10. A trench device manufactured by the manufacturing method according to claim 1.

11. The trench device according to claim 10, wherein the trench device comprises a substrate, a first oxide layer, a hard mask layer, and a dielectric layer, which are sequentially stacked, as well as a first window, a second window, a first trench, and a second trench;
the first window is located in a critical device region of the substrate and through the first oxide layer, the hard mask layer, and the dielectric layer, and the second window is located in a non-critical device region of the substrate and through the first oxide layer, the hard mask layer, and the dielectric layer; and
the first trench is located in a region corresponding to the first window and formed in the substrate, and the second trench is located in a region corresponding to the second window and formed in the substrate.
